(19) United States
(12) Patent Application Publication
(10) Pub. No.: US 2011/0095313 A1
(43) Pub. Date: Apr. 28, 2011

(54) LIGHT EMITTING DIODE AND MANUFACTURING METHOD THEREOF

(76) Inventors: Peng-Yi Wu, Taichung City (TW); Shih-Cheng Huang, Hsinchu City (TW); Po-Min Tu, Chiayi County (TW); Wen-Yu Lin, Taichung County (TW); Tzu-Chien Hong, Kaohsiung City (TW)

(21) Appl. No.: 12/891,731

(22) Filed: Sep. 27, 2010

(30) Foreign Application Priority Data
Oct. 28, 2009 (CN) 200910208519.8

(51) Int. Cl. H01L 33/30

(52) U.S. Cl. 257/94; 438/47; 257/E33.023

(57) ABSTRACT

A method for manufacturing light-emitting diode (LED) first provides a substrate, then a protrusive patterned layer is formed on the substrate. The protrusive patterned layer exposes portions of the substrate, and the exposed portions are defined as a plurality of exposed regions. Next, a plurality of island semiconductor multi-layer is individually formed in each exposed region of the substrate.

### BACKGROUND OF THE INVENTION

1. Field of the Invention

The present invention relates to a light emitting diode (LED) and a manufacturing method thereof, and more particularly, to a manufacturing method capable of reducing stresses between materials.

2. Description of the Prior Art

LEDs are widely used in lighting and display technology due its advantages of low power consumption, environment friendliness, small size, and easy installment. In the LED technology, group III-nitride compounds such as GaN, AlGaN InGaN and AlInGaN are particularly important because it exhibit excellent features such as wide energy gap, high luminous efficiency and a superior light emission characteristic: it covers almost the entire visible light spectrum.

Please refer to FIGS. 1-2, which are cross-sectional views of a conventional LED. The conventional LED 100 includes GaN-based III-V compound semiconductor materials grown on a substrate 102 made of sapphire or SiC. As shown in FIG. 1, the conventional LED 100 is obtained by sequentially forming a buffer layer 104, an n-type epitaxial layer 106, an active layer 108, a p-type epitaxial layer 110 and a contact layer 112 on the substrate 102. Then, as shown in FIG. 2, an n-type electrode 114 and a p-type electrode 116 are formed and followed by separating each individual LED 100. However, it is about an amount of 16% in lattice mismatch existing between the GaN-based III-V compound semiconductor materials and the substrate 102. Consequently, defects such as dislocation are always found in the epitaxial layers formed on the substrate 102. Furthermore, dislocation extends while the thickness of the growing epitaxial layers is increased and strain stress is generated. It is well-known that the strain stress between the materials deteriorates power conversion efficiency, operating characteristic, and lifetime of the LED. Furthermore, those skilled in the art would easily realize that the strain stress is released along the strain release boundary between the materials, while the strain release boundary is often found at the edge of a LED. Accordingly, those unreleased strain stress accumulates in the epitaxial layers and finally causing cracks for releasing the strain stress, and the crack even makes the LED failure.

Therefore, the prior art developed methods to reduce the problems caused by stress accumulation in the epitaxial layers. For example, metal-organic chemical vapor deposition (MOCVD) is introduced to form the buffer layer 104 of AlN or GaN in awareness of the feature of heterogenerous growth of the buffer layer 104. Another approach is provided to form the active layer 104 having superlattice structure. Or, as shown in FIG. 1, by introducing epitaxial lateral overgrowth (ELOG), that is to form a plurality of bar-like substances 118 on the buffer layer 104 for changing the distribution of strain stress in the buffer layer 104 and the growing direction of dislocation. As a result, the epitaxial layer 106, 110 and the active layer 108 formed over the buffer layer 104 have less dislocation density and strain stress. However, higher dislocation density and stress accumulation still occur in the gap 129 between the bar-like substances 118. In addition, the prior art also introduces a crack preventive layer (not shown) to obstruct extension of dislocation in the epitaxial layers.

It is found the lattice dismatch is increased when aluminum content in the epitaxial layer such as AlₓGa₁₋ₓN is increased, that means where if the quantity of X is higher, the lattice mismatch is larger. Therefore the methods provided by the prior art still cannot effectively solve the problem while those methods further increase process complexity and cost. It is also observed that the bar-like substances 118 and the crack preventive layer deteriorate the optical performance of the LED. Thus, it is a difficult issue for fabrication that how to reduce the strain stress, avoid the cracking in the epitaxial layers and improve the performance of the device without further complicating the manufacturing methods for the LED.

### SUMMARY OF THE INVENTION

One aspect of the present invention is to provide a manufacturing method of LED that effectively reduces the strain stress without complicating the manufacturing method.

According to one aspect of the present invention, a LED is provided. The LED comprises a substrate, a protrusive patterned layer positioned on the substrate and exposing portions of the substrate to form a plurality of exposed regions, and a plurality of individual island semiconductor multi-layer respectively positioned in each exposed region.

According to another aspect of the present invention, a manufacturing method of an LED is provided. The method comprises steps of providing a substrate, forming a protrusive patterned layer exposing portions of the substrate to form a plurality of exposed regions on the substrate, and forming an individual island semiconductor multi-layer respectively in each exposed regions.

According to the LED provided by the present invention, the surface of the substrate, on which the semiconductor layers are formed, is divided by the protrusive patterned layer, resulting in the plurality of exposed regions. And the individual island semiconductor multi-layer is respectively formed in each of the exposed regions. Consequently, the ratio of strain release boundary in per unit area is increased and thus efficiency of stress release is improved and the semiconductor multi-layer of high quality is obtained without cracking.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 are cross-sectional views of a conventional LED; and

FIGS. 3-7 are schematic drawings illustrating a manufacturing method of a LED provided by a preferred embodiment of the present invention; wherein FIG. 4 is a cross-sectional view taken along A-A′ line in FIG. 3.

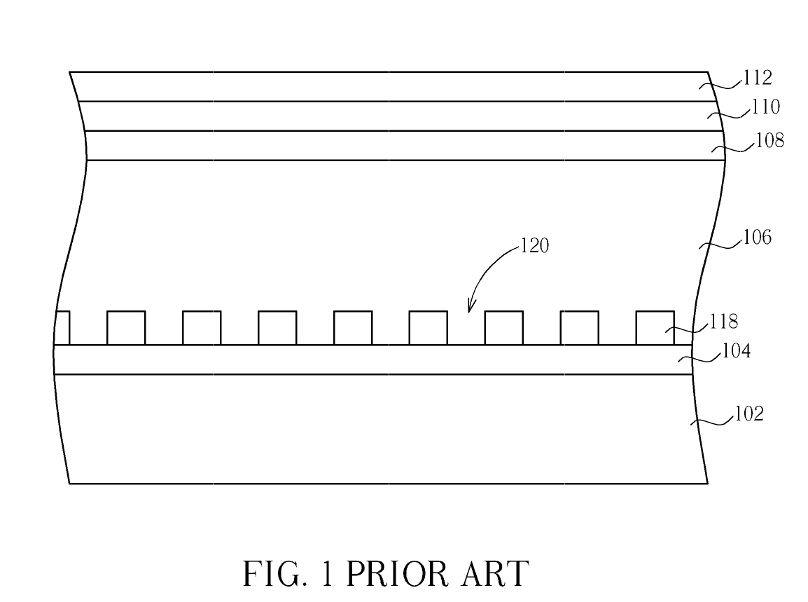

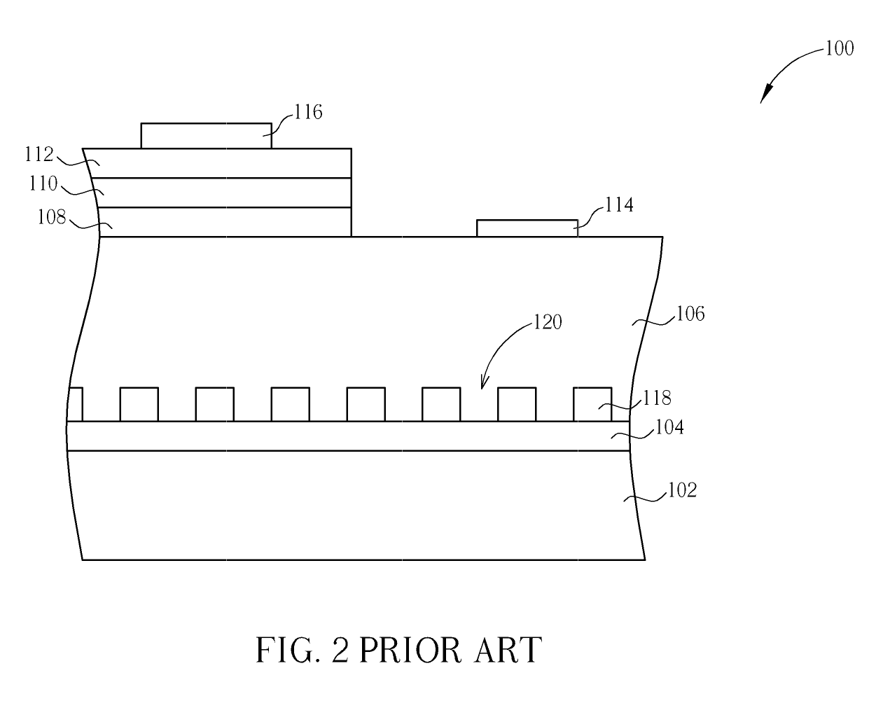

### DETAILED DESCRIPTION

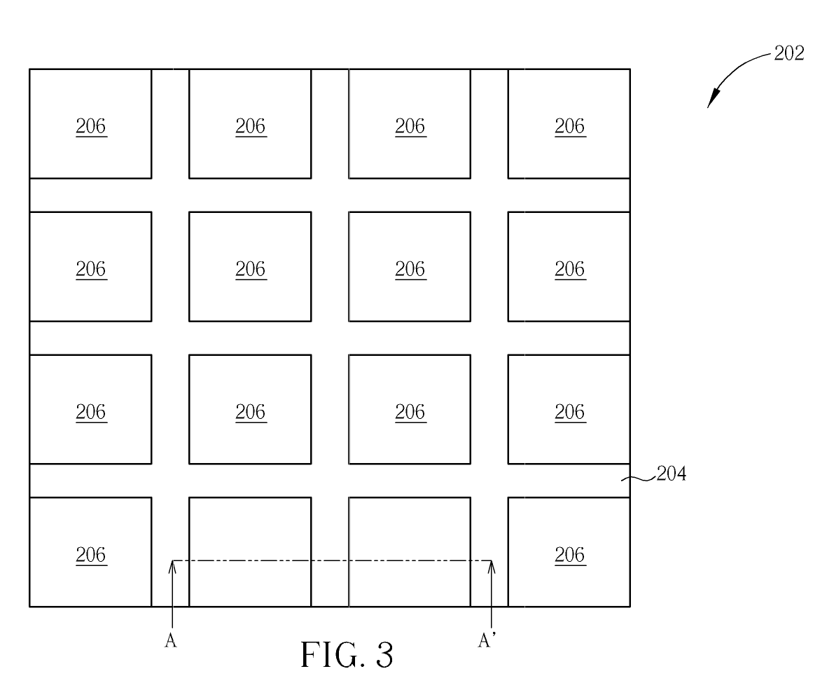

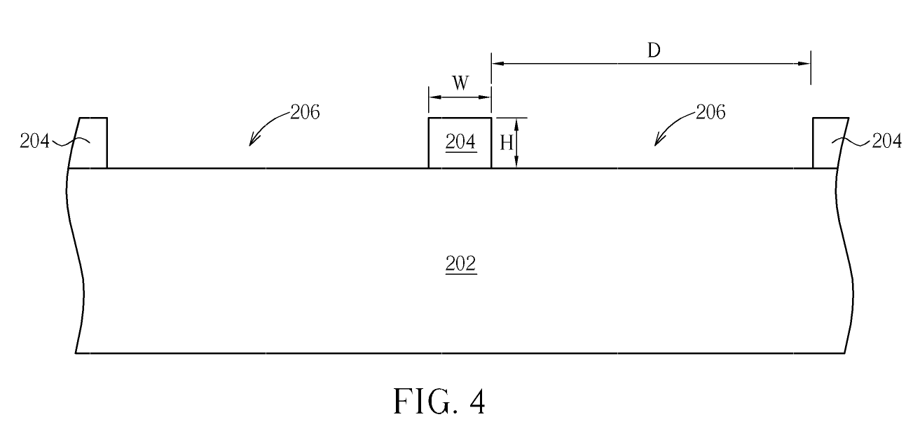

Please refer to FIGS. 3-7, which are schematic drawings illustrating a manufacturing method of a LED provided by a preferred embodiment of the present invention. Please refer to FIG. 3 and FIG. 4 first, wherein FIG. 4 is a cross-sectional view taken along A-A′ line in FIG. 3. As shown in FIG. 3, a substrate 202 including sapphire, silicon carbide (SiC), silicon (Si), zinc oxide (ZnO), magnesium oxide (MgO), or gallium arsenide (GaAs) is provided. Then, a protrusive patterned layer 204 is formed on the substrate 202. The protrusive patterned layer 204 can include a mesh pattern as shown in FIG. 3, but not limited to this. The protrusive patterned layer 204 exposes portions of the substrate 202 to form a plurality of exposed regions 206 as shown in FIG. 4.

Please refer to FIG. 3 and FIG. 4 again. As mentioned above, the protrusive patterned layer 204 having a mesh pattern. In detail, the protrusive patterned layer 204 is formed by interlacing a plurality of strip-like structures on the substrate 202. It is noteworthy that though the exposed regions 206 in the preferred embodiment are formed to have square shape, it is not limited to form the protrusive patterned layer 204 having other hollow-out pattern on the substrate 202. For example, the exposed regions 206 can have shape of rectangle, rhombus, hexagon, or round while retaining the teachings of the invention. Furthermore, the protrusive patterned layer 204 has a height “H” larger than 0.01 micrometer (μm) and a width “W” larger than 2 μm. Additionally, a width “D” of each exposed region 206 is between 50 and 2000 μm.

With consideration of temperatures for forming other layers of the LED in the subsequent steps, the protrusive patterned layer 204 is required to endure temperature higher than 1000° C. Therefore the protrusive patterned layer 204 in the preferred embodiment includes a high-temperature endurable material, preferably a dielectric material such as silicon oxide (SiO), silicon nitride (SiN), or silicon oxynitride (SiON) formed by chemical vapor deposition (CVD), low-pressure chemical vapor deposition (LPCVD), or plasma-enhanced chemical vapor deposition (PECVD). With conventional patterning method that omitted herein for the sake of brevity, the protrusive patterned layer 204 is formed on the substrate 202.

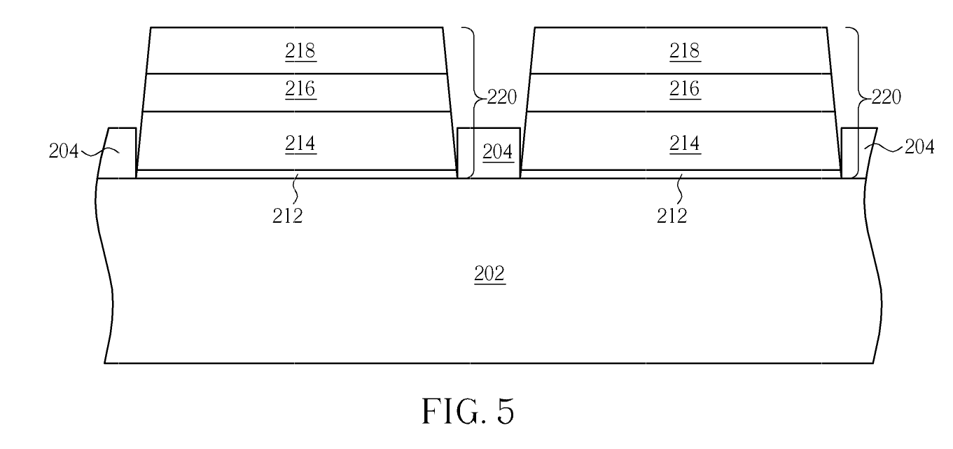

Please refer to FIG. 5. Next, a buffer layer 212, an n-type epitaxial layer 214, an active layer 216 and a p-type epitaxial layer 218 are sequentially formed on the substrate 202. The active layer 216 serving as the light emitting layer can include a multiple quantum well (MQW) structure. The buffer layer 212, the n-type epitaxial layer 214, the active layer 216, and the p-type epitaxial layer 218 construct an island semiconductor multi-layer 220 in each exposed region 206, individually. In the preferred embodiment, the individual island semiconductor multi-layer 220 includes GaN-based III-V compound semiconductor materials, preferably the AlₓGa₁₋ₓN and the quantity of X is larger than 0.2. It is noteworthy that because the epitaxial material grows along surface of the substrate, the buffer layer 212, the n-type epitaxial layer 214, the active layer 216 and the p-type epitaxial layer 218 are formed and a plurality of individual island semiconductor multi-layer 220 are formed as shown in FIG. 5 with the protrusive patterned layer 204 having the dielectric layer serving as the boundary between each of the island semiconductor multi-layers 220. Since essential layers of the island semiconductor multi-layer 220 in the preferred embodiment are well-known to those skilled in the art, those details are omitted herein in the interest of brevity.

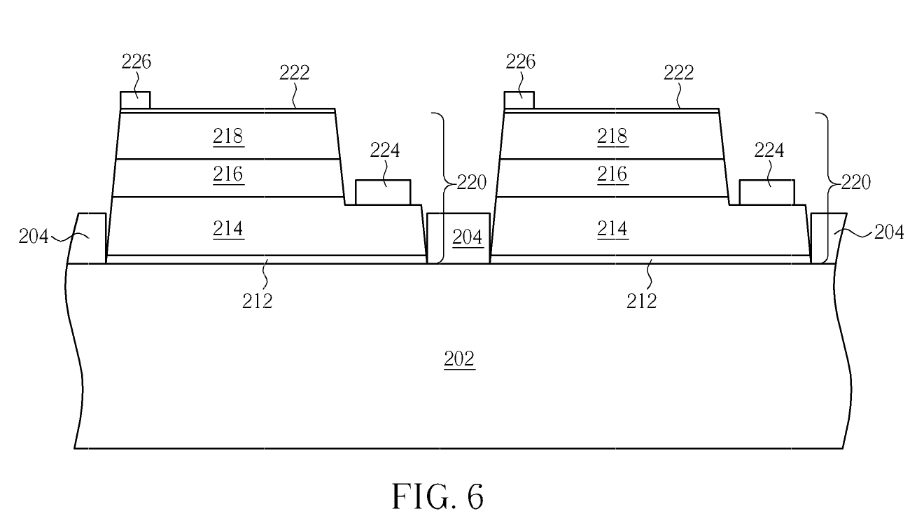

Please refer to FIG. 6. In order to prevent current crowding, a transparent conductive layer 222 is subsequently formed on the p-type epitaxial layer 218 and followed by removing a portion of the transparent conductive layer 222, a portion of the p-type epitaxial layer 218, a portion of the active layer 216 and a portion of the n-type epitaxial layer 214. Accordingly, the n-type epitaxial layer 214 is exposed. As shown in FIG. 6, an n-type electrode 224 and a p-type electrode 226 are then formed respective on the n-type epitaxial layer 214 and the transparent conductive layer 222.

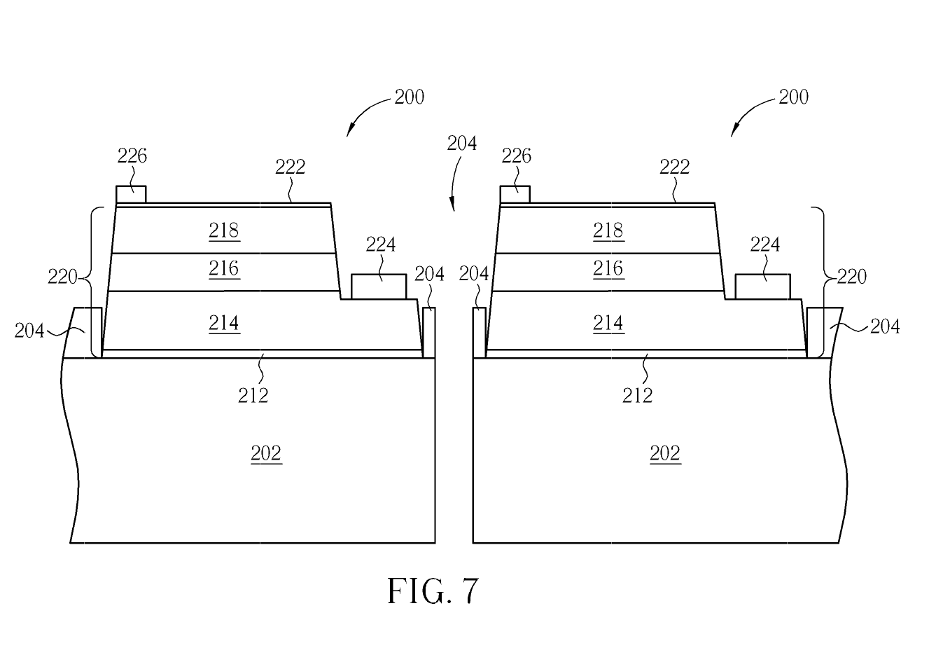

Please refer to FIG. 7. After forming the island semiconductor multi-layer 220, the n-type electrode 224 and the p-type electrode 226, a cutting process is performed to cut the protrusive patterned layer 204 and the substrate 202, thus a plurality of LED devices 200 are obtained. It is noteworthy the protrusive patterned layer 204 not only serves as the boundary of the island semiconductor multi-layers 220, but also serves as the scribe line in the cutting process with the cutting machine cuts the protrusive patterned layer 204 and the underneath the substrate 202.

According to the manufacturing method of an LED provided by the present invention, the surface of the substrate 202 is divided into the plurality of exposed regions 206 by the protrusive patterned layer 204, and the island semiconductor multi-layer 220 is individually formed in each of the exposed regions 206. Therefore the protrusive patterned layer 204 serves as the boundary between the island semiconductor multi-layers 220 for forming the LED device after the cutting process. As mentioned above, since the strain stress is released at the strain release boundary which is often formed on the edge of the semiconductor layers, the strain stress are effectively released when the ratio of strain release boundary in per unit area is increased. In the case that the semiconductor layers are in bulk before cutting process in the prior art, the ratio of the strain release boundary of the bulk semiconductor layers before the cutting process is about 78%. However the ratio of the strain release boundary to the island semiconductor multi-layers 220 before the cutting process is improved to 112.6% according to the method provided by the present invention. In other words, by breaking up the whole semiconductor layer into parts, that are the island semiconductor multi-layers 220 before the cutting process, the ratio of the strain release boundary in per unit area is greatly increased. Consequently, the strain stress accumulated in the semiconductor layers is effectively released and thus semiconductor layers of high quality are obtained.

Furthermore, different from the prior art that introducing bar-like substances or crack preventive layer, the method of manufacturing LED provided by the present invention improves both of the stress release efficiency and the LED performance without adding any layers or other structure in the essential semiconductor layers or complicating the method it self. Accordingly, the provide method is more preferable for forming AlₓGa₁₋ₓN with the quantity of X larger than 0.25.

Those skilled in the art will readily observe that numerous modifications and alterations of the device and method may be made while retaining the teachings of the invention.

What is claimed is:

1. A light emitting diode (LED) comprising:
a substrate;
a protrusive patterned layer positioned on the substrate and exposing portions of the substrate to form a plurality of exposed regions; and
a plurality of individual island semiconductor multi-layer respectively positioned in each exposed region.

2. The LED of claim 1, wherein the substrate comprises sapphire, silicon carbide (SiC), silicon (Si), zinc oxide (ZnO), magnesium oxide (MgO), or gallium arsenide (GaAs).

3. The LED of claim 1, wherein the protrusive patterned layer comprises a mesh pattern.

4. The LED of claim 1, wherein the protrusive patterned layer comprises a high-temperature endurable material.

5. The LED of claim 1, wherein the protrusive patterned layer has a height larger than 0.01 micrometer (μm).

6. The LED of claim 1, wherein the protrusive patterned layer has a width larger than 2 μm.

7. The LED of claim 1, wherein a width of the exposed regions is between 50 and 2000 μm.

8. The LED of claim 1, wherein the island semiconductor multi-layer comprises GaN-based III-V compound semiconductor materials.

9. A manufacturing method of an LED comprising:
providing a substrate;
forming a protrusive patterned layer on the substrate, the protrusive patterned layer exposing a portion of the substrate to form a plurality of exposed regions; and
forming an individual island semiconductor multi-layer respectively in each exposed region.

10. The manufacturing method of an LED according to claim 9, wherein the substrate comprises sapphire, silicon carbide (SiC), silicon (Si), zinc oxide (ZnO), magnesium oxide (MgO), or gallium arsenide (GaAs).

11. The manufacturing method of an LED according to claim 9, wherein the protrusive patterned layer comprises a mesh pattern.

12. The manufacturing method of an LED according to claim 9, wherein the protrusive patterned layer comprises a high-temperature endurable material.

13. The manufacturing method of an LED according to claim 9, wherein the protrusive patterned layer has a height larger than 0.01 μm.

14. The manufacturing method of an LED according to claim 9, wherein the protrusive patterned layer has a width larger than 2 μm.

15. The manufacturing method of an LED according to claim 9, wherein a width of the exposed regions is between 50 and 2000 μm.

16. The manufacturing method of an LED according to claim 9, wherein the step of forming the island semiconductor multi-layer further comprises sequentially forming a buffer layer, an n-type epitaxial layer, an active layer, and a p-type epitaxial layer in the exposed regions.

17. The manufacturing method of an LED according to claim 16, wherein the island semiconductor multi-layer comprises GaN-based III-V compound semiconductor materials.

18. The manufacturing method of an LED according to claim 16, further comprising a step of forming a transparent conductive layer on the p-type epitaxial layer.

19. The manufacturing method of an LED according to claim 18, further comprising a step of forming an n-type electrode and a p-type electrode respectively on the n-type epitaxial layer and the transparent conductive layer.

20. The manufacturing method of an LED according to claim 19, further comprising a step of cutting the protrusive patterned layer and the substrate after forming the n-type electrode and the p-type electrode.
